(19) United States
(12) Patent Application Publication
(10) Pub. No.: US 2025/0085322 A1
(43) Pub. Date: Mar. 13, 2025

(54) CIRCUIT AND METHOD FOR MEASURING CAPACITANCE AND CAPACITANCE-VOLTAGE CHARACTERISTICS OF MICROELECTRONIC DEVICE

(71) Applicant: Central China Normal University, Wuhan (CN)

(72) Inventors: Yingqing Xia, Wuhan (CN); Dong Wang, Wuhan (CN); Chaosong Gao, Wuhan (CN); Xiangming Sun, Wuhan (CN); Mengqi Sun, Wuhan (CN); Ping Yang, Wuhan (CN)

(73) Assignee: Central China Normal University, Wuhan (CN)

(21) Appl. No.: 18/827,104

(22) Filed: Sep. 6, 2024

(30) Foreign Application Priority Data
Sep. 8, 2023 (CN) 202311165627.8

(51) Int. Cl. G01R 27/26

(52) U.S. Cl. CPC G01R 27/2605

(57) ABSTRACT

Provided are a circuit and method for measuring capacitance and capacitance-voltage characteristics of a microelectronic device. The circuit includes a pulse generation sub-circuit, a sub-circuit P, and a sub-circuit N. The pulse generation sub-circuit generates clock pulses CLK1 and CLK2 with non-overlapping active levels. The sub-circuit P includes a first current mirror, a first large capacitor, a first transmission gate, a second transmission gate, a first OR gate, a first AND gate, a first NOT gate, a second NOT gate, and a third NOT gate. The sub-circuit N includes a second current mirror, a second large capacitor, a third transmission gate, a fourth transmission gate, a second OR gate, a second AND gate, a fourth NOT gate, a fifth NOT gate, a sixth NOT gate, and a seventh NOT gate.

### CROSS REFERENCE TO RELATED APPLICATION

This patent application claims the benefit and priority of Chinese Patent Application No. 202311165627.8, filed with the China National Intellectual Property Administration on Sep. 8, 2023, the disclosure of which is incorporated by reference herein in its entirety as part of the present application.

### TECHNICAL FIELD

The present disclosure relates to the technical field of integrated circuit design and semiconductor manufacturing and testing, and particularly, to a circuit and method for measuring capacitance and capacitance-voltage characteristics of a microelectronic device.

### BACKGROUND

With continuous advancements in semiconductor technology and the shrinking of feature sizes, the parasitic capacitance in integrated circuit chips has decreased significantly, now typically in the femtofarad (fF) range. Accurately measuring capacitance and capacitance-voltage characteristics of microelectronic devices presents an extremely challenging task. Addressing issues such as high cost, complexity in control, stringent test environment requirements, and narrow bias voltage ranges associated with some measurement methods, the present disclosure provides a characteristic measurement circuit and method. The circuit offers low cost, simple control, and enables accurate measurement of fF or sub-fF capacitance and capacitance-voltage characteristics of microelectronic devices.

### SUMMARY

The present disclosure aims to provide a circuit and method for measuring capacitance and capacitance-voltage characteristics of a microelectronic device, to address the problem of measuring fF or sub-fF capacitance and capacitance-voltage characteristics of the microelectronic device.

The technical solutions of the present disclosure are as follows:

A circuit for measuring capacitance and capacitance-voltage characteristics of a microelectronic device includes a pulse generation sub-circuit, a sub-circuit P and a sub-circuit N, where
the pulse generation sub-circuit generates clock pulses CLK1 and CLK2 with non-overlapping active levels;
the sub-circuit P includes a first current mirror, a first large capacitor, a first transmission gate, a second transmission gate, a first OR gate, a first AND gate, a first NOT gate, a second NOT gate, and a third NOT gate; a first output terminal of the first current mirror is connected to a first terminal of the first transmission gate, a second terminal of the first transmission gate is connected to a first terminal of the second transmission gate, and a second terminal of the second transmission gate is connected to a VBP; a second output terminal of the first current mirror is grounded through the first large capacitor; an input terminal of the first OR gate is connected to the clock pulse CLK1, a CTRP, and a VSS, an output terminal of the first OR gate is connected to a first control terminal of the first transmission gate, and the output terminal of the first OR gate is further connected to a second control terminal of the first transmission gate through the first NOT gate; an input terminal of the first AND gate is connected to a VDD, the CTRP passing through the second NOT gate, and the clock pulse CLK2, an output terminal of the first AND gate is connected to a first control terminal of the second transmission gate, and the output terminal of the first AND gate is further connected to a second control terminal of the second transmission gate through the third NOT gate;
the sub-circuit N includes a second current mirror, a second large capacitor, a third transmission gate, a fourth transmission gate, a second OR gate, a second AND gate, a fourth NOT gate, a fifth NOT gate, a sixth NOT gate, and a seventh NOT gate; a first output terminal of the second current mirror is connected to a first terminal of the third transmission gate, a second terminal of the third transmission gate is connected to a first terminal of the fourth transmission gate, and a second terminal of the fourth transmission gate is connected to a VBN; a second output terminal of the second current mirror is grounded through the second large capacitor; an input terminal of the second OR gate is connected to the clock pulse CLK1, a CTRN, and an LHN passing through the fourth NOT gate, an output terminal of the second OR gate is connected to a first control terminal of the third transmission gate, and the output terminal of the second OR gate is further connected to a second control terminal of the third transmission gate through the fifth NOT gate; an input terminal of the second AND gate is connected to the LHN, the CTRN passing through the sixth NOT gate, and the clock pulse CLK2, an output terminal of the second AND gate is connected to a first control terminal of the fourth transmission gate, and the output terminal of the second AND gate is further connected to a second control terminal of the fourth transmission gate through the seventh NOT gate;
one terminal of a to-be-measured device capacitor is connected to a connection node between the first transmission gate and the second transmission gate, and the other terminal of the to-be-measured device capacitor is connected to a connection node between the third transmission gate and the fourth transmission gate; and
high potential terminals of the first current mirror and the second current mirror are each connected to a VDA, substrates of all P-channel metal-oxide semiconductor (PMOS) transistors in the four transmission gates are each connected to a negative power supply VSB, substrates of all N-channel metal-oxide semiconductor (NMOS) transistors are each connected to a positive power supply VDD, positive power supplies of all the gate circuits are each connected to the VDD, and low power supplies of all the gate circuits are each connected to the VSS, while low power supplies of the second OR gate, the second AND gate, the fourth NOT gate, the fifth NOT gate, and the seventh NOT gate are each connected to a VSA.

A method for measuring capacitance of a microelectronic device using the above circuit for measuring capacitance and capacitance-voltage characteristics of a microelectronic device includes:
grounding a VSS, a VSA, a VBP, and a VBN, and connecting a VDD to a positive power supply;
when a CTRP is at a low level and a CTRN and an LHN are at a high level, turning off a third transmission gate and turning on a fourth transmission gate in a sub-circuit N, connecting one terminal of a to-be-measured device capacitor Cx to the VBN through the fourth transmission gate, connecting the to-be-measured device capacitor Cx in parallel to a sub-circuit P; when a clock pulse CLK1 is at an active level and a clock pulse CLK2 is at an inactive level, turning off a second transmission gate and turning on a first transmission gate, to enable the circuit to charge the to-be-measured device capacitor through the first transmission gate; or when the clock pulse CLK2 is at an active level and the clock pulse CLK1 is at an inactive level, turning off the first transmission gate and turning on the second transmission gate, to discharge the to-be-measured device capacitor through the second transmission gate;
when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, where in a period of time, voltage at both terminals of the first large capacitor Cw increases in an equal step on a microscopic level and increases linearly on a macroscopic level; obtaining a curve slope corresponding to each to-be-measured device capacitor Cx, where the to-be-measured device capacitor Cx is connected in parallel to an equivalent parasitic capacitor C0p; obtaining capacitance of the to-be-measured device capacitor Cx according to the linearly increasing curve slope, to obtain a relationship between capacitance Cx+C0p and the curve slope; and
removing C0p from Cx+C0p to obtain capacitance of Cx, where the two sub-circuits work synchronously: setting a CTRP and a CTRN at a low level, setting an LHN at a high level, and bridging the to-be-measured device capacitor Cx between the sub-circuit P and the sub-circuit N; turning on and off the first transmission gate and the third transmission gate synchronously, and turning off and on the second transmission gate and the fourth transmission gate synchronously, where potentials at both terminals of the to-be-measured device capacitor bridged between the two sub-circuits are equal, and the CTRP and the CTRN are the beginning and end of a low-level period with zero charge variation; obtaining parasitic capacitance C0p according to a current curve slope, and obtaining the capacitance of the to-be-measured device capacitor: Cx=(Cx+C0p)−C0p.

A method for measuring capacitance-voltage characteristics of a microelectronic device using the above circuit for measuring capacitance and capacitance-voltage characteristics of a microelectronic device includes:
grounding a VSS, a VSA, a VBP, and a VBN, and enabling two sub-circuits to work synchronously: setting a CTRP and a CTRN at a low level, setting an LHN at a high level, and bridging a to-be-measured device capacitor Cd between connection nodes of a sub-circuit P and a sub-circuit N; turning on and off a first transmission gate and a third transmission gate synchronously, and turning off and on a second transmission gate and a fourth transmission gate synchronously, where potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS, the VBP, and the CTRP, setting the CTRP at a low level, setting the CTRN at a high level, connecting the VSA and the LHN to a negative power supply VSB, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, where in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBN to fall between the negative power supply VSB and a VDA, and obtaining the capacitance-voltage characteristics of the to-be-measured device capacitor Cd.

A method for measuring forward and reverse-biased capacitance-voltage characteristics of a microelectronic device using the above circuit for measuring capacitance and capacitance-voltage characteristics of a microelectronic device includes:
replacing a VDD connected to an input terminal of a first AND gate in a sub-circuit P with an LHP, and replacing a VSS connected to an input terminal of a first OR gate with an LHP passing through a NOT gate;
grounding a VSS, a VBP, and a VBN, and enabling two sub-circuits to work synchronously: setting a CTRP and a CTRN at a low level, setting the LHP and an LHN at a high level, and bridging a to-be-measured device capacitor Cd between connection nodes of the sub-circuit P and a sub-circuit N; turning on and off a first transmission gate and a third transmission gate synchronously, turning off and on a second transmission gate and a fourth transmission gate synchronously, where potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS and the VBP, setting the LHN and the CTRP at a low level, and setting the LHN and the CTRN at a high level, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, where in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p;
changing a value of the power supply VBN to fall between the negative power supply VSB and a VDA, and obtaining the capacitance-voltage characteristics of the to-be-measured device capacitor Cd;
grounding the VSS and the VBN, setting the LHP and the CTRN at a low level, setting the LHN and CTRP at a high level, turning on the second transmission gate, turning off the first transmission gate, connecting one terminal of the to-be-measured device capacitor Cd to the power supply VBN through the second transmission gate, connecting the other terminal of the to-be-measured device capacitor Cd to the connection node of the sub-circuit N, and connecting the to-be-measured device capacitor Cd in parallel to the sub-circuit N;
when the clock pulse CLK1 is at an active level and the clock pulse CLK2 is at an inactive level, turning off the fourth transmission gate and turning on the third transmission gate, to enable the circuit to charge the to-be-measured device capacitor Cd and the equivalent parasitic capacitor C0P through the third transmission gate; or when the clock pulse CLK2 is at an active level and the clock pulse CLK1 is at an inactive level, turning off the third transmission gate and turning on the fourth transmission gate, to discharge the to-be-measured device capacitor through the fourth transmission gate; when the to-be-measured device capacitor is charged, mirroring the charging current as a charging current i3 of a second large capacitor through a second current mirror in the sub-circuit N; periodically and continuously charging and discharging the to-be-measured device capacitor, to synchronously charge the second large capacitor Cw2 with the mirror current i3 during a charging period, where in a period of time, voltage at both terminals of the second large capacitor Cw2 increases in an equal step on a microscopic level and increases linearly on a macroscopic level; obtaining the total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBP to fall between the ground and the VDA, and obtaining the reverse-biased capacitance-voltage characteristics of the device.

A circuit for measuring capacitance and capacitance-voltage characteristics of a plurality of devices includes the above pulse generation sub-circuit, and a plurality of pairs of sub-circuit Ps and sub-circuit Ns, where a to-be-measured device capacitor is arranged between connection nodes of each pair of sub-circuit P and sub-circuit N; all the sub-circuit Ps are connected in parallel to share a first current mirror, and all the sub-circuit Ns are connected in parallel to share a second current mirror.

A method for measuring capacitance and capacitance-voltage characteristics of a plurality of devices using the above circuit for measuring capacitance and capacitance-voltage characteristics of a plurality of devices includes:
when measuring capacitance or capacitance-voltage characteristics of an i^{th} to-be-measured device, setting at a high level CTRPs and CTRNs in sub-circuit Ps and sub-circuit Ns in which the remaining to-be-measured devices are located, to disconnect the circuits from the first current mirror and the second current mirror, where only the sub-circuit P and the sub-circuit N in which the i^{th} to-be-measured device is located is connected to the first current mirror and the second current mirror and work normally; and
obtaining the capacitance and capacitance-voltage characteristics of the i^{th} to-be-measured device by using the above method for measuring capacitance-voltage characteristics of a microelectronic device.

A circuit for measuring forward and reverse-biased capacitance-voltage characteristics of a plurality of devices includes the above pulse generation sub-circuit, and a plurality of pairs of sub-circuit Ps and sub-circuit Ns, where a to-be-measured device capacitor is arranged between connection nodes of each pair of sub-circuit P and sub-circuit N; all the sub-circuit Ps are connected in parallel to share a first current mirror, and all the sub-circuit Ns are connected in parallel to share a second current mirror; VDDs connected to input terminals of first AND gates in all the sub-circuit Ps are replaced by LHPs, and VSSs connected to input terminals of first OR gates are replaced by LHPs passing through NOT gates.

A method for measuring forward and reverse-biased capacitance-voltage characteristics of a plurality of devices using the above circuit for measuring forward and reverse-biased capacitance-voltage characteristics of a plurality of devices includes:
when measuring capacitance, capacitance-voltage characteristics, or forward and reverse-biased capacitance-voltage characteristics of an i^{th} to-be-measured device, setting at a high level CTRPs and CTRNs in sub-circuit Ps and sub-circuit Ns in which the remaining to-be-measured devices are located, to disconnect the circuits from a first current mirror and a second current mirror, where only a sub-circuit P and a sub-circuit N in which the i^{th} to-be-measured device is located are connected to the first current mirror and the second current mirror and work normally; and
obtaining the capacitance, the capacitance-voltage characteristics, and the forward and reverse-biased capacitance-voltage characteristics of the i^{th} to-be-measured device by using the above method for measuring forward and reverse-biased capacitance-voltage characteristics of a microelectronic device.

A circuit for measuring capacitance and capacitance-voltage characteristics of a plurality of substrate-connected devices includes the above pulse generation sub-circuit and the sub-circuit P, and further includes a plurality of substrate-connected sub-circuits, where
an i^{th} substrate-connected sub-circuit includes a fifth transmission gate, a sixth transmission gate, a to-be-measured device capacitor Cdi and a to-be-measured device capacitor Csj; a connection node of the sub-circuit P is connected to a first terminal of the fifth transmission gate, a second terminal of the fifth transmission gate is connected to one terminal of the to-be-measured device capacitor Cdi, and the other terminal VSD of the to-be-measured device capacitor Cdi is connected to a substrate negative power supply VSB; the connection node of the sub-circuit P is further connected to a first terminal of the sixth transmission gate, a second terminal of the sixth transmission gate is connected to one terminal of the to-be-measured device capacitor Csj, and the other terminal VSC of the to-be-measured device capacitor Csj is connected to a low power supply; and

a first control terminal of the fifth transmission gate is connected to a CTRDi, and the CTRDi is connected to a second control terminal of the fifth transmission gate through a NOT gate; a first control terminal of the sixth transmission gate is connected to a CTRCj, and the CTRCj is connected to a second control terminal of the sixth transmission gate through a NOT gate.

A method for measuring capacitance and capacitance-voltage characteristics of a plurality of substrate-connected devices using the above circuit for measuring capacitance and capacitance-voltage characteristics of a plurality of substrate-connected devices includes:
grounding a VSS, a VSA, and a VBP, and setting control signals CTRCj and CTRDi at a high level, turning off all transmission gates, and enabling a sub-circuit P to work normally;
when a clock pulse CLK1 is at an active level and a clock pulse CLK2 is at an inactive level, turning off a second transmission gate and turning on a first transmission gate, to enable the circuit to charge a total equivalent parasitic capacitor C0 through the first transmission gate; or when the clock pulse CLK2 is at an active level and the clock pulse CLK1 is at an inactive level, turning off the first transmission gate and turning on the second transmission gate, to discharge the parasitic capacitor through the second transmission gate;
when the capacitor is charged, mirroring a charging current i1 as a charging current i2 through a first current mirror; periodically and continuously charging and discharging the capacitor, to synchronously charge a first large capacitor Cw with the current i2 during a charging period, where in a period of time, voltage at both terminals of the first large capacitor Cw increases in an equal step on a microscopic level and increases linearly on a macroscopic level; and obtaining parasitic capacitance C0 according to a current curve slope;
setting a transmission gate control signal CTRDi of the to-be-measured device Cdi at a low level, to connect the to-be-measured device to a connection node of the sub-circuit P, and setting other control signals at a high level, to disconnect other devices;
when the clock pulse CLK1 is at an active level and the clock pulse CLK2 is at an inactive level, turning off the second transmission gate and turning on the first transmission gate, to enable the circuit to charge the to-be-measured device capacitor Cdi and the equivalent parasitic capacitor C0 through the first transmission gate; or when the clock pulse CLK2 is at an active level and the clock pulse CLK1 is at an inactive level, turning off the first transmission gate and turning on the second transmission gate, to discharge the to-be-measured device capacitor and the parasitic capacitor through the second transmission gate; when the capacitor is charged, mirroring the charging current i1 as i2 through the first current mirror; periodically and continuously charging and discharging the capacitor, to synchronously charge the first large capacitor Cw with the mirror current i2 during a charging period, where in a period of time, voltage at both terminals of the first large capacitor Cw increases in an equal step on a microscopic level and increases linearly on a macroscopic level; obtaining total capacitance Cdi+C0 of the to-be-measured device capacitor and the parasitic capacitor according to a current curve slope, to obtain capacitance of the to-be-measured device capacitor: Cdi=(Cdi+C0)−C0; and
changing a power supply VSD, that is, a value of a substrate negative power supply VSB, to obtain the to-be-measured device capacitance or capacitance-voltage characteristics.

Compared with the prior art, the present disclosure has the following advantages and beneficial effects:

The present disclosure discloses a low-cost, simple, convenient, and characteristic measurement circuit and method, which can accurately measure fF or sub-fF capacitance, capacitance-voltage characteristics, and forward and reverse-biased capacitance-voltage characteristics of the microelectronic device.

### BRIEF DESCRIPTION OF THE DRAWINGS

FIG. 1 is a basic diagram of a circuit for measuring capacitance of a microelectronic device;

FIGS. 2A-2B are curve graph showing a relationship between time and voltage of two terminals of an external large capacitor Cw, FIG. 2A is a macro relationship graph, and FIG. 2B is a micro relationship graph;

FIG. 3 is a diagram of a circuit for measuring capacitance-voltage characteristics of a device;

FIG. 4 is a diagram of a circuit for measuring forward and reverse-biased capacitance-voltage characteristics of a device;

FIG. 5 is a diagram of a circuit for measuring capacitance and capacitance-voltage characteristics of a plurality of devices;

FIG. 6 is a diagram of a circuit for measuring capacitance and forward and reverse-biased capacitance-voltage characteristics of a plurality of devices; and

FIG. 7 is a diagram of a circuit for measuring capacitance and capacitance-voltage characteristics of a to-be-measured substrate-connected device.

### DETAILED DESCRIPTION OF THE EMBODIMENTS

In order to make the objectives, technical solutions, and advantages of the present disclosure more clear, the present disclosure is further described in detail below with reference to the accompanying drawings and examples. It should be understood that the specific embodiments described herein are intended merely to explain the present disclosure, rather than to limit the present disclosure. Further, the technical features involved in the various examples of the present disclosure described below may be combined with each other as long as they do not constitute a conflict with each other.

The present disclosure disclose a circuit and method for measuring capacitance and forward and reverse-biased capacitance-voltage characteristics of a microelectronic device in integrated circuit chips, which can be applied to the measurement of capacitance and forward and reverse-biased capacitance-voltage characteristics of the microelectronic device in semiconductor chips.

### 1. Basic Method for Measuring Capacitance of a Microelectronic Device

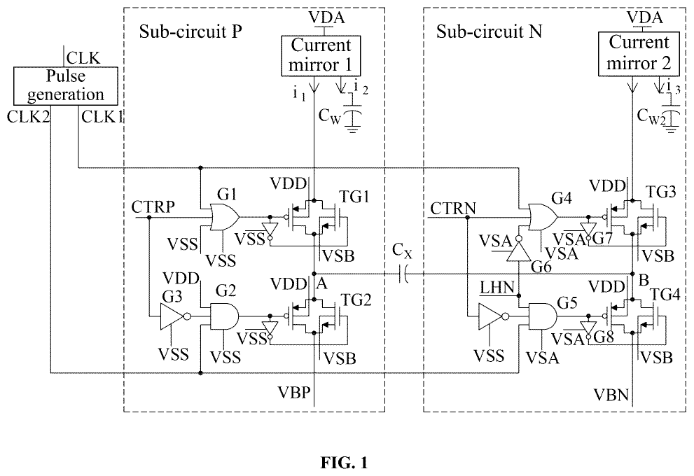

As shown in FIG. 1, a basic circuit in the method includes a pulse generation sub-circuit and two sub-circuits (a sub-circuit P and a sub-circuit N). The two sub-circuits have the same structure and parameters, and a to-be-measured device capacitor Cx is bridged between nodes A and B of the two sub-circuits. Each sub-circuit includes a current mirror, two transmission gates, and corresponding logic control circuits. In the circuit, substrates of all PMOS transistors are connected to a negative power supply VSB, substrates of all NMOS transistors are connected to a positive power supply VDD, and a high potential terminal of the current mirror is connected to a VDA. A positive power supply of the gate circuit is also connected to the VDD, and a low power supply is connected to a VSS. However, the low power supplies of gate circuits G4, G5, G6, G7, and G8 are each connected to a VSA. Driven by an input clock pulse CLK, the pulse generation sub-circuit generates clock pulses CLK1 and CLK2 with non-overlapping active levels (low level is active in FIG. 1).

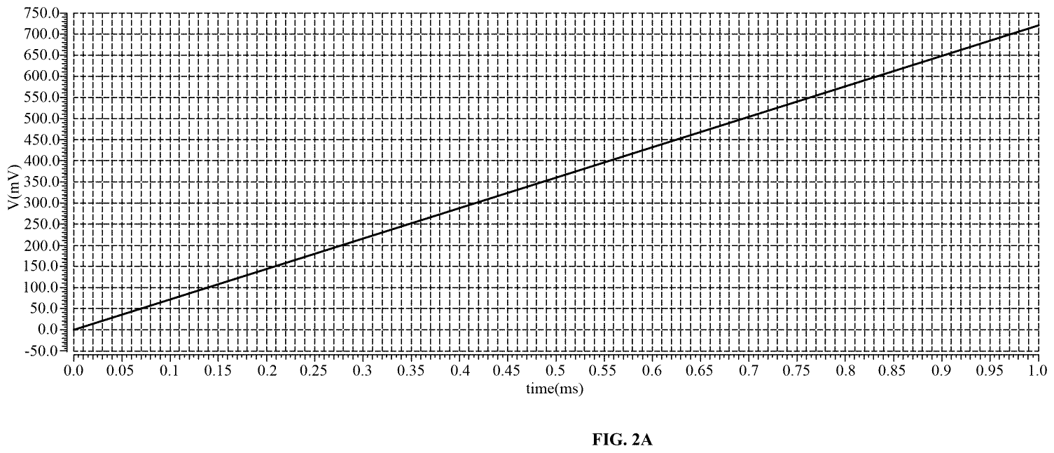

When measuring the capacitance of the microelectronic device, the VSS, VSA, VBP, and VBN are all grounded, and the VDD is connected to the positive power supply. When the CTRP is at a low level (ground) and the CTRN and LHN are at a high level (VDD), a transmission gate TG3 in the sub-circuit N is turned off and a transmission gate TG4 is turned on. One terminal of the to-be-measured device capacitor Cx is connected to the VBN (ground) through the TG4. In this case, the to-be-measured device capacitor Cx is connected in parallel to the sub-circuit P. When the clock pulse CLK1 is at an active level, the clock pulse CLK2 is definitely at an inactive level, the transmission gate TG2 is turned off, and the transmission gate TG1 is turned on, such that the circuit charges the to-be-measured device (and the parasitic) capacitor through the transmission gate TG1. When the clock pulse CLK2 is at an active level, the clock pulse CLK1 is definitely at an inactive level, the transmission gate TG1 is turned off, and the transmission gate TG2 is turned on, such that the to-be-measured device (and the parasitic) capacitors are discharged through the transmission gate TG2. When the capacitor is charged, a charging current i1 is mirrored as i2(=i1) through a current mirror 1 in the circuit. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level, as shown in FIGS. 2A-2B. FIG. 2A is a macro relationship graph, and FIG. 2B is a micro relationship graph.

Different values of Cx are selected to obtain a corresponding curve slope. The to-be-measured device capacitor Cx is connected in parallel to some equivalent parasitic capacitors (denoted as C0p), and the capacitance of the parasitic capacitors can be obtained according to the linearly increasing curve slope, so as to obtain the relationship between the capacitance (Cx+C0p) and the curve slope.

In order to remove C0p from (Cx+C0p) and obtain the capacitance of Cx, the two sub-circuits are enabled to work synchronously: The CTRP and CTRN are at a low level, the LHN is at a high level, and the to-be-measured capacitor Cx is bridged between the sub-circuit P and the sub-circuit N. Because the two sub-circuits have the same structure and parameters, the transmission gate TG1 and the transmission gate TG3 are turned on and off synchronously, and the transmission gate TG2 and the transmission gate TG4 are turned off and on synchronously. In this case, potentials at both terminals of the to-be-measured device capacitor bridged between the two sub-circuits are equal, the CTRP and CTRN are the beginning and end of a low-level period with zero charge variation. The parasitic capacitance C0p can be obtained according to a current curve slope. Therefore, the capacitance of the to-be-measured device capacitor is obtained: Cx=(Cx+C0p)−C0p.

### 2. Method for Measuring Device Capacitance-Voltage Characteristics

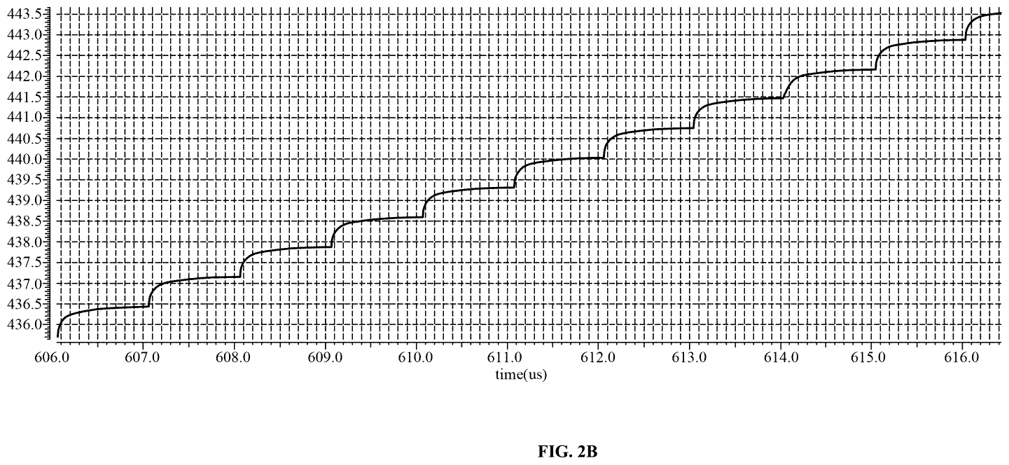

The method can measure the capacitance-voltage characteristics of the device. A to-be-measured device Cd is bridged between nodes A and B of the above two sub-circuits, as shown in FIG. 3.

Measurement steps are as follows:

(1) The VSS, VSA, VBP, and VBN are all rounded, and the two sub-circuits are enabled to work synchronously: The CTRP and CTRN are at a low level, the LHN is at a high level, and a device capacitor (corresponding capacitance is Cd) is bridged between the nodes A and B of the sub-circuit P and the sub-circuit N. Because the two sub-circuits have the same structure and parameters, the transmission gate TG1 and the transmission gate TG3 are turned on and off synchronously, and the transmission gate TG2 and the transmission gate TG4 are turned off and on synchronously. In this case, potentials at both terminals of the to-be-measured capacitor bridged between the two sub-circuits are equal, the CTRP and CTRN are the beginning and end of a low-level period with zero charge variation. The parasitic capacitance C0p can be obtained according to a current curve slope.

(2) The VSS, VBP, and CTRP are grounded, the CTRP is at a low level (ground), and the CTRN is at a high level (VDD). The VSA and LHN are connected to the negative power supply VSB. In this case, the TG4 is turned on and TG3 is turned off. A terminal of the to-be-measured device (equivalent capacitor Cd) is connected to the power supply VBN (which can be appropriately adjusted between the negative power supply VSB and VDA) through the TG4, the other terminal is connected to the node A of the sub-circuit P, and the to-be-measured device (equivalent capacitor Cd) is connected in parallel to the sub-circuit P.

When the clock pulse CLK1 is at an active level, the clock pulse CLK2 is at an inactive level, the transmission gate TG2 is turned off, and the transmission gate TG1 is turned on, such that the circuit charges the to-be-measured device capacitor Cd and the parasitic capacitor C0P through the transmission gate TG1. When the clock pulse CLK2 is at an active level, the clock pulse CLK1 is at an inactive level, the transmission gate TG1 is turned off, and the transmission gate TG2 is turned on, such that the to-be-measured device (and the parasitic) capacitors are discharged through the transmission gate TG2. When the capacitor is charged, the charging current i1 is mirrored as i2 (=i1) through the current mirror 1 in the circuit. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level. The total capacitance Cd+C0p of the to-be-measured device capacitor and the parasitic capacitor can be obtained according to the current curve slope. Therefore, the capacitance of the to-be-measured device capacitor is obtained: Cd=(Cd+C0p)−C0p.

The capacitance-voltage characteristics of the device can be obtained by changing the value of the power supply VBN.

### 3. Method for Measuring Forward and Reverse-Biased Capacitance-Voltage Characteristics of a Device

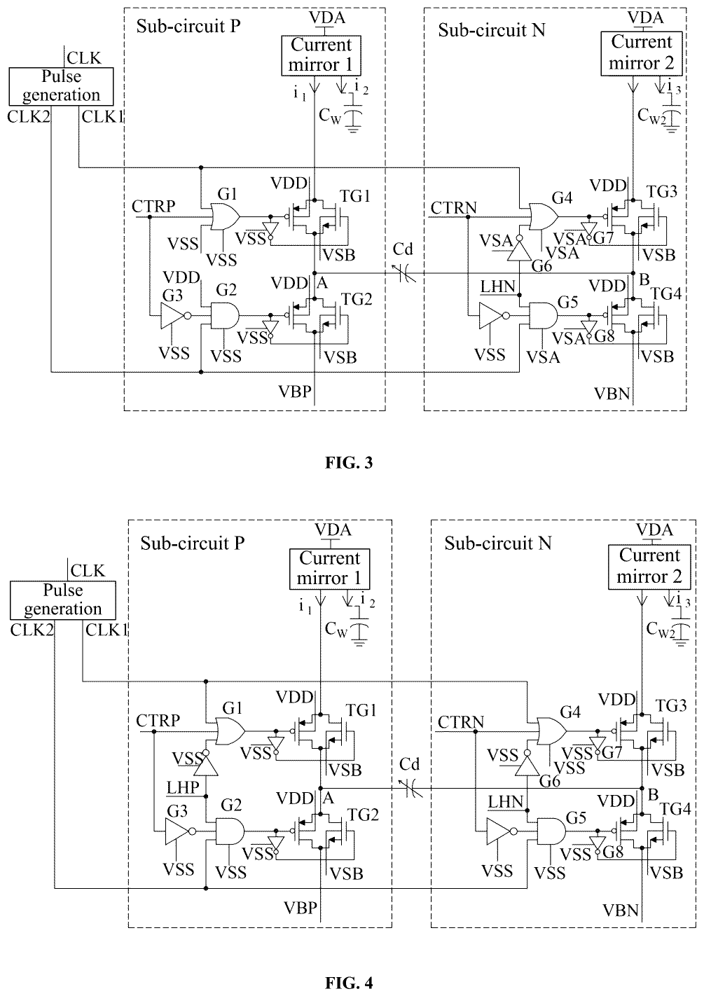

The method can measure the forward and reverse-biased capacitance-voltage characteristics of the device. The to-be-measured device Cd is bridged between nodes A and B of the above two sub-circuits, as shown in FIG. 4.

Measurement steps are as follows:

(1) The VSS, VBP, and VBN are all grounded, and the two sub-circuits are enabled to work synchronously: The CTRP and CTRN are at a low level, the LHP and LHN are at a high level, and a device capacitor (corresponding capacitance is Cd) is bridged between the nodes A and B of the sub-circuit P and the sub-circuit N. Because the two sub-circuits have the same structure and parameters, the transmission gate TG1 and the transmission gate TG3 are turned on and off synchronously, and the transmission gate TG2 and the transmission gate TG4 are turned off and on synchronously. In this case, potentials at both terminals of the to-be-measured capacitor bridged between the two sub-circuits are equal, the CTRP and CTRN are the beginning and end of a low-level period with zero charge variation. The parasitic capacitance C0p can be obtained according to a current curve slope.

(2) The VSS and VBP are grounded, the LHN and CTRP are at a low level (ground), and the LHP and CTRN are at a high level (VDD). In this case, the TG4 is turned on and TG3 is turned off. A terminal of the to-be-measured device (equivalent capacitor Cd) is connected to the power supply VBN (which can be appropriately adjusted between the ground and VDA) through the TG4, the other terminal is connected to the node A of the sub-circuit P, and the to-be-measured device (equivalent capacitor Cd) is connected in parallel to the sub-circuit P.

When the clock pulse CLK1 is at an active level, the clock pulse CLK2 is at an inactive level, the transmission gate TG2 is turned off, and the transmission gate TG1 is turned on, such that the circuit charges the to-be-measured device capacitor Cd and the parasitic capacitor C0P through the transmission gate TG1. When the clock pulse CLK2 is at an active level, the clock pulse CLK1 is at an inactive level, the transmission gate TG1 is turned off, and the transmission gate TG2 is turned on, such that the to-be-measured device (and the parasitic) capacitors are discharged through the transmission gate TG2. When the capacitor is charged, the charging current i1 is mirrored as i2 (=i1) through the current mirror 1 in the circuit. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level. The total capacitance Cd+C0p of the to-be-measured device capacitor and the parasitic capacitor can be obtained according to the current curve slope. Therefore, the capacitance of the to-be-measured device capacitor is obtained: Cd=(Cd+C0p)−C0p.

The capacitance-voltage characteristics of the device can be obtained by changing the value of the power supply VBN.

(3) The VSS and VBN are grounded, the LHP and CTRN are at a low level (ground), and the LHN and CTRP are at a high level (VDD). In this case, the TG2 is turned on and TG1 is turned off. A terminal of the to-be-measured device (equivalent capacitor Cd) is connected to the power supply VBP (which can be appropriately adjusted between the ground and VDA) through the TG2, the other terminal is connected to the node B of the sub-circuit N, and the to-be-measured device (equivalent capacitor Cd) is connected in parallel to the sub-circuit N.

When the clock pulse CLK1 is at an active level, the clock pulse CLK2 is at an inactive level, the transmission gate TG4 is turned off, and the transmission gate TG3 is turned on, such that the circuit charges the of the to-be-measured device capacitor Cd and the parasitic capacitor C0P through the transmission gate TG3. When the clock pulse CLK2 is at an active level, the clock pulse CLK1 is at an inactive level, the transmission gate TG3 is turned off, and the transmission gate TG4 is turned on, such that the to-be-measured device (and the parasitic) capacitors are discharged through the transmission gate TG4. When the capacitor is charged, the charging current is mirrored as i3 through a current mirror 2 in the circuit. By periodically and continuously charging and discharging the capacitor, the external large capacitor Cw2 is charged synchronously with the mirror current i3 during the charging period. In a period of time, the voltage at both terminals of the external large capacitor Cw2 increases in an equal step on the microscopic level and increases linearly on the macroscopic level. The total capacitance Cd+C0p of the to-be-measured device capacitor and the parasitic capacitor can be obtained according to the current curve slope. Therefore, the capacitance of the to-be-measured device capacitor is obtained: Cd=(Cd+C0p)−C0p.

The forward and reverse-biased capacitance-voltage characteristics of the device can be obtained by changing the value of the power supply VBP.

### 4. Method for Measuring Capacitance and Capacitance-Voltage Characteristics of a Plurality of Devices

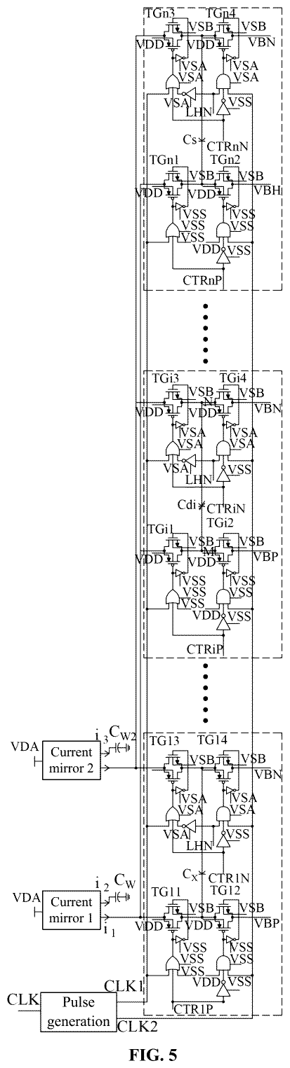

The method can measure the capacitance and capacitance-voltage characteristics of a plurality of devices. In terms of circuit, above-mentioned sub-circuit Ps for measuring the device capacitance are connected in parallel and share the current mirror 1, and the sub-circuit Ns for measuring the device capacitance are connected in parallel and share the current mirror 2, as shown in FIG. 5.

When measuring capacitance or capacitance-voltage characteristics of an i^{th} device, CTRjPs and CTRjNs in all other circuits for measuring the device capacitance are connected to the high level VDD (j≠i), to disconnect the circuits from the current mirror 1 and the current mirror 2, and connect the remaining devices to the low power supply (VBP or VBN). Only the circuit for measuring capacitance of the i^{th} device is connected to the current mirror 1 and the current mirror 2 and works normally. Measurement steps are as follows:

(1) The VSS, VSA, VBP, and VBN are all grounded, and the two sub-circuits of the circuit for measuring capacitance of the i^{th} device work synchronously: The CTRIP and CTRiN are at a low level (ground), the LHN is at a high level (VDD), and a device capacitor (corresponding capacitance is Cdi) is bridged between nodes M and N of the sub-circuit P and the sub-circuit N. Because the two sub-circuits have the same structure and parameters, the transmission gate TGi1 and the transmission gate TGi3 are turned on and off synchronously, and the transmission gate TGi2 and the transmission gate TGi4 are turned off and on synchronously. In this case, potentials at both terminals of the to-be-measured device capacitor bridged between the two sub-circuits are equal, the CTRiP and CTRiN are the beginning and end of a low-level period with zero charge variation. The parasitic capacitance Cip can be obtained according to a current curve slope.

(2) The VSS, VBP, and CTRiP are grounded, and the CTRiN is at a high level (VDD). The VSA and LHN are connected to the negative power supply VSB. In this case, the TGi4 is turned on and the TGi3 is turned off. A terminal of the to-be-measured device (equivalent capacitor Cdi) is connected to the power supply VBN (which can be appropriately adjusted between the negative power supply VSB and (close to) VDA) through the TGi4, the other terminal is connected to the node M of the sub-circuit P, and the to-be-measured device (equivalent capacitor Cdi) is connected in parallel to the sub-circuit P.

When the clock pulse CLK1 is at an active level, the clock pulse CLK2 is at an inactive level, the transmission gate TGi2 is turned off, and the transmission gate TGi1 is turned on, such that the circuit charges the to-be-measured device capacitor Cdi and the parasitic capacitor CiP through the transmission gate TGi1. When the clock pulse CLK2 is at an active level, the clock pulse CLK1 is at an inactive level, the transmission gate TGi1 is turned off, and the transmission gate TGi2 is turned on, such that the to-be-measured device (and the parasitic) capacitors are discharged through the transmission gate TGi2. When the capacitor is charged, the charging current i1 is mirrored as i2 (=i1) through the current mirror 1 in the circuit. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level. The total capacitance Cdi+Cip of the to-be-measured device capacitor and the parasitic capacitor is obtained according to the current curve slope. Therefore, the capacitance of the to-be-measured device is obtained Cdi=(Cdi+Cip)−Cip.

The capacitance-voltage characteristics of the i^{th} device can be obtained by changing the value of the power supply VBN.

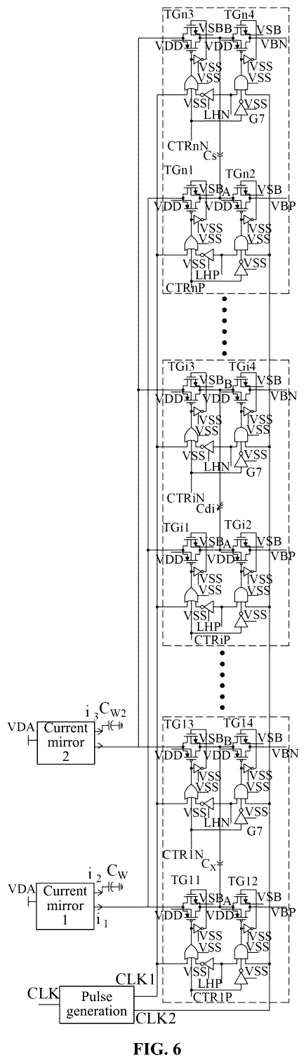

As shown in FIG. 6, similar to FIG. 3, the capacitance-voltage characteristics of the device under opposite bias voltage can be obtained by reversing the high-low potential relationship between VBP and VBN and adjusting the voltage difference.

### 5. Method for Measuring Capacitance and Capacitance-Voltage Characteristics of a Plurality of Substrate-Connected Devices

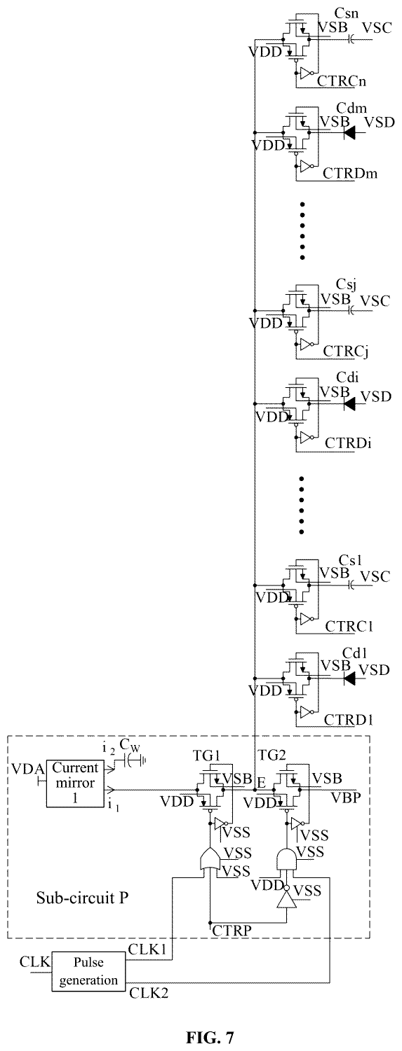

When the to-be-measured device needs to be connected to the substrate, the circuit shown in FIG. 7 can be used to measure the capacitance and capacitance-voltage characteristics of a plurality of devices.

In the circuit shown in FIG. 7, the sub-circuit P of the above circuit for measuring capacitance is connected to the current mirror 1. A terminal VSD of each to-be-measured device Cdi is connected to the substrate negative power supply VSB. A terminal VSC of a to-be-measured device Csj is connected to the low power supply (VSS), and the other terminal is connected in parallel to a node E of the sub-circuit P through a transmission gate circuit, and on/off of the transmission gate is controlled by a control signal (CTRCj or CTRDi).

Measurement steps are as follows:

(1) The VSS, VSA, and VBP are grounded, and the control signal CTRCj or CTRDi is set at a high level, all transmission gates are turned off, and the sub-circuit P of the capacitance measuring circuit works normally.

When the clock pulse CLK1 is at an active level, the clock pulse CLK2 is at an inactive level, the transmission gate TG2 is turned off, and the transmission gate TG1 is turned on, such that the circuit charges the total equivalent parasitic capacitor C0 through the transmission gate TG1. When the clock pulse CLK2 is at an active level, the clock pulse CLK1 is at an inactive level, the transmission gate TG1 is turned off, and the transmission gate TG2 is turned on, such that the parasitic capacitor is discharged through the transmission gate TG2. When the capacitor is charged, the charging current i1 is mirrored as i2 (=i1) through the current mirror 1. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level. The parasitic capacitance C0 can be obtained according to the current curve slope.

(2) The transmission gate control signal CTRDi of the to-be-measured device Cdi is set at a low level (ground), to connect the to-be-measured device to the node E of the sub-circuit P, and other control signals (CTRCj or CTRDk, k≠i) are set at a high level (VDD), to disconnect other devices.

When the clock pulse CLK1 is at an active level, the clock pulse CLK2 is at an inactive level, the transmission gate TG2 is turned off, and the transmission gate TG1 is turned on, such that the circuit charges the to-be-measured device capacitor Cdi and the equivalent parasitic capacitor C0 through the transmission gate TG1. When the clock pulse CLK2 is at an active level, the clock pulse CLK1 is at an inactive level, the transmission gate TG1 is turned off, and the transmission gate TG2 is turned on, such that the to-be-measured device capacitor and the parasitic capacitor are discharged through the transmission gate TG2. When the capacitor is charged, the charging current i1 is mirrored as i2 (=i1) through the current mirror 1. By periodically and continuously charging and discharging the capacitor, the external large capacitor Cw is charged synchronously with the current i2 during the charging period. In a period of time, the voltage at both terminals of the external large capacitor Cw increases in an equal step on the microscopic level and increases linearly on the macroscopic level. The total capacitance Cdi+C0 of the to-be-measured device capacitor and the parasitic capacitor can be obtained according to the current curve slope. Therefore, the capacitance of the to-be-measured device satisfies Cdi=(Cdi+C0)−C0.

The power supply VSD (that is, the substrate negative power supply VSB) is changed, to obtain the capacitance or capacitance-voltage characteristics of the to-be-measured device.

### 6. Calibration With Known On-Chip Capacitance

In FIG. 1, FIG. 3, and FIG. 4, the to-be-measured device may be a capacitor (such as mimcap, the same below) with known on-chip capacitance, and this type of capacitance is small and accurate. The corresponding curve slope can be measured using the above method, so as to calibrate the relationship between the capacitance (Cx+C0p) and the curve slope in the process.

In FIG. 5 and FIG. 6, the plurality of devices may be different capacitors Cs with known on-chip capacitance, and the relationship between the capacitance (Cs+Cnp) and the curve slope in the process can be calibrated in a larger measurement range.

In FIG. 7, the plurality of devices may be different capacitors Csj with known on-chip capacitance, and the relationship between the capacitance (Csj+C0) and the curve slope in the process can be calibrated in a larger measurement range.

In order to ensure more accurate measurement, a large number of (for example, 10,000) above capacitors with known capacitance can be connected in parallel and led to external pins for accurate measurement, so as to obtain the accurate capacitance of each single capacitor for calibration.

It should be noted that the external capacitors Cw and Cw2 should be fully discharged before each measurement using the above method. When measuring the curve slopes of the voltage at both terminals of external capacitors Cw and Cw2 with time, two points (or more points) in the area with high linearity are selected to measure and calculate the curve slopes, so as to improve the measurement accuracy.

The positive power supply VDA and the negative power supply VSB are set according to the bias voltage range and the adopted process. Different bias voltages can be set by adjusting the value of the power supply VBN between the negative power supply VSB and (close to) VDA. Adjusting VBP between the ground and the positive power supply VDA can set the potential change of the node A in the sub-circuit P connected to the to-be-measured device capacitor. When measuring the parasitic capacitance C0p, the value of VBN should be equal to that of VBP.

When designing the circuit layout, some matching techniques should be adopted to enable the current mirrors and the sub-circuits to be identical and consistent as possible, so as to reduce the measurement error.

Certainly, the present disclosure can not only accurately measure fF or sub-fF capacitance, capacitance-voltage characteristics, and forward and reverse-biased capacitance-voltage characteristics of the microelectronic device, but is also suitable for devices with larger capacitance. Moreover, the method and technology of the present disclosure can be applied to the field of capacitive sensors.

It should be pointed out that, based on needs of implementation, each step/component described in the present disclosure can be divided into more steps/components, or two or more steps/components or some operations of the steps/components can be combined into a new step/component to achieve the objective of the present disclosure.

It is easy for those skilled in the art to understand that the foregoing descriptions are merely preferred embodiments of the present disclosure, and not intended to limit the present disclosure. Any modifications, equivalent replacements, improvements, and the like made within the spirit and principle of the present disclosure shall all fall within the protection scope of the present disclosure.

What is claimed is:

1. A circuit for measuring capacitance and capacitance-voltage characteristics of a microelectronic device, comprising a pulse generation sub-circuit, a sub-circuit P and a sub-circuit N, wherein
the pulse generation sub-circuit is configured to generate clock pulses CLK1 and CLK2 with non-overlapping active levels;
the sub-circuit P comprises a first current mirror, a first large capacitor, a first transmission gate, a second transmission gate, a first OR gate, a first AND gate, a first NOT gate, a second NOT gate, and a third NOT gate; a first output terminal of the first current mirror is connected to a first terminal of the first transmission gate, a second terminal of the first transmission gate is connected to a first terminal of the second transmission gate, and a second terminal of the second transmission gate is connected to a VBP; a second output terminal of the first current mirror is grounded through the first large capacitor; an input terminal of the first OR gate is connected to the clock pulse CLK1, a CTRP, and a VSS, an output terminal of the first OR gate is connected to a first control terminal of the first transmission gate, and the output terminal of the first OR gate is further connected to a second control terminal of the first transmission gate through the first NOT gate; an input terminal of the first AND gate is connected to a VDD, the CTRP passing through the second NOT gate, and the clock pulse CLK2, an output terminal of the first AND gate is connected to a first control terminal of the second transmission gate, and the output terminal of the first AND gate is further connected to a second control terminal of the second transmission gate through the third NOT gate;
the sub-circuit N comprises a second current mirror, a second large capacitor, a third transmission gate, a fourth transmission gate, a second OR gate, a second AND gate, a fourth NOT gate, a fifth NOT gate, a sixth NOT gate, and a seventh NOT gate; a first output terminal of the second current mirror is connected to a first terminal of the third transmission gate, a second terminal of the third transmission gate is connected to a first terminal of the fourth transmission gate, and a second terminal of the fourth transmission gate is connected to a VBN; a second output terminal of the second current mirror is grounded through the second large capacitor; an input terminal of the second OR gate is connected to the clock pulse CLK1, a CTRN, and an LHN passing through the fourth NOT gate, an output terminal of the second OR gate is connected to a first control terminal of the third transmission gate, and the output terminal of the second OR gate is further connected to a second control terminal of the third transmission gate through the fifth NOT gate; an input terminal of the second AND gate is connected to the LHN, the CTRN passing through the sixth NOT gate, and the clock pulse CLK2, an output terminal of the second AND gate is connected to a first control terminal of the fourth transmission gate, and the output terminal of the second AND gate is further connected to a second control terminal of the fourth transmission gate through the seventh NOT gate;
one terminal of a to-be-measured device capacitor is connected to a connection node between the first transmission gate and the second transmission gate, and the other terminal of the to-be-measured device capacitor is connected to a connection node between the third transmission gate and the fourth transmission gate; and
high potential terminals of the first current mirror and the second current mirror are each connected to a VDA, substrates of all P-channel metal-oxide semiconductor (PMOS) transistors in the four transmission gates are each connected to a negative power supply VSB, substrates of all N-channel metal-oxide semiconductor (NMOS) transistors are each connected to a positive power supply VDD, positive power supplies of all gate circuits are each connected to the VDD, and low power supplies of all the gate circuits are each connected to the VSS, while low power supplies of the second OR gate, the second AND gate, the fourth NOT gate, the fifth NOT gate, and the seventh NOT gate are each connected to a VSA.

2. A method for measuring capacitance of a microelectronic device using the circuit for measuring capacitance and capacitance-voltage characteristics of a microelectronic device according to claim 1, comprising:
grounding a VSS, a VSA, a VBP, and a VBN, and connecting a VDD to a positive power supply;
when a CTRP is at a low level and a CTRN and an LHN are at a high level, turning off a third transmission gate and turning on a fourth transmission gate in a sub-circuit N, connecting one terminal of a to-be-measured device capacitor Cx to the VBN through the fourth transmission gate, connecting the to-be-measured device capacitor Cx in parallel to a sub-circuit P; when a clock pulse CLK1 is at an active level and a clock pulse CLK2 is at an inactive level, turning off a second transmission gate and turning on a first transmission gate, to enable the circuit to charge the to-be-measured device capacitor through the first transmission gate; or when the clock pulse CLK2 is at an active level and the clock pulse CLK1 is at an inactive level, turning off the first transmission gate and turning on the second transmission gate, to discharge the to-be-measured device capacitor through the second transmission gate;
when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, wherein in a period of time, voltage at both terminals of the first large capacitor Cw increases in an equal step on a microscopic level and increases linearly on a macroscopic level; obtaining a curve slope corresponding to each to-be-measured device capacitor Cx, wherein the to-be-measured device capacitor Cx is connected in parallel to an equivalent parasitic capacitor C0p; obtaining capacitance of the to-be-measured device capacitor Cx according to the linearly increasing curve slope, to obtain a relationship between capacitance Cx+C0p and the curve slope; and
removing C0p from Cx+C0p to obtain capacitance of Cx, wherein the two sub-circuits work synchronously: setting a CTRP and a CTRN at a low level, setting an LHN at a high level, and bridging the to-be-measured device capacitor Cx between the sub-circuit P and the sub-circuit N;
turning on and off the first transmission gate and the third transmission gate synchronously, and turning off and on the second transmission gate and the fourth transmission gate synchronously, wherein potentials at both terminals of the to-be-measured device capacitor bridged between the two sub-circuits are equal, and the CTRP and the CTRN are the beginning and end of a low-level period with zero charge variation; obtaining parasitic capacitance C0p according to a current curve slope, and obtaining the capacitance of the to-be-measured device capacitor: Cx=(Cx+C0p)−C0p.

3. A method for measuring capacitance-voltage characteristics of a microelectronic device using the circuit for measuring capacitance and capacitance-voltage characteristics of a microelectronic device according to claim 1, comprising:
grounding a VSS, a VSA, a VBP, and a VBN, and enabling two sub-circuits to work synchronously: setting a CTRP and a CTRN at a low level, setting an LHN at a high level, and bridging a to-be-measured device capacitor Cd between connection nodes of a sub-circuit P and a sub-circuit N; turning on and off a first transmission gate and a third transmission gate synchronously, and turning off and on a second transmission gate and a fourth transmission gate synchronously, wherein potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS, the VBP, and the CTRP, setting the CTRP at a low level, setting the CTRN at a high level, connecting the VSA and the LHN to a negative power supply VSB, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, wherein in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBN to fall between the negative power supply VSB and a VDA, and obtaining the capacitance-voltage characteristics of the to-be-measured device capacitor Cd.

4. A method for measuring forward and reverse-biased capacitance-voltage characteristics of a microelectronic device using the circuit for measuring capacitance and capacitance-voltage characteristics of a microelectronic device according to claim 1, comprising:
replacing a VDD connected to an input terminal of a first AND gate in a sub-circuit P with an LHP, and replacing a VSS connected to an input terminal of a first OR gate with an LHP passing through a NOT gate;
grounding a VSS, a VBP, and a VBN, and enabling two sub-circuits to work synchronously: setting a CTRP and a CTRN at a low level, setting the LHP and an LHN at a high level, and bridging a to-be-measured device capacitor Cd between connection nodes of the sub-circuit P and a sub-circuit N; turning on and off a first transmission gate and a third transmission gate synchronously, turning off and on a second transmission gate and a fourth transmission gate synchronously, wherein potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS and the VBP, setting the LHN and the CTRP at a low level, and setting the LHN and the CTRN at a high level, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, wherein in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p;
changing a value of the power supply VBN to fall between the negative power supply VSB and a VDA, and obtaining the capacitance-voltage characteristics of the to-be-measured device capacitor Cd;
grounding the VSS and the VBN, setting the LHP and the CTRN at a low level, setting the LHN and CTRP at a high level, turning on the second transmission gate, turning off the first transmission gate, connecting one terminal of the to-be-measured device capacitor Cd to the power supply VBN through the second transmission gate, connecting the other terminal of the to-be-measured device capacitor Cd to the connection node of the sub-circuit N, and connecting the to-be-measured device capacitor Cd in parallel to the sub-circuit N;
when the clock pulse CLK1 is at an active level and the clock pulse CLK2 is at an inactive level, turning off the fourth transmission gate and turning on the third transmission gate, to enable the circuit to charge the to-be-measured device capacitor Cd and the equivalent parasitic capacitor C0P through the third transmission gate; or when the clock pulse CLK2 is at an active level and the clock pulse CLK1 is at an inactive level, turning off the third transmission gate and turning on the fourth transmission gate, to discharge the to-be-measured device capacitor through the fourth transmission gate; when the to-be-measured device capacitor is charged, mirroring the charging current as a charging current i3 of a second large capacitor through a second current mirror in the sub-circuit N; periodically and continuously charging and discharging the to-be-measured device capacitor, to synchronously charge the second large capacitor Cw2 with the mirror current i3 during a charging period, wherein in a period of time, voltage at both terminals of the second large capacitor Cw2 increases in an equal step on a microscopic level and increases linearly on a macroscopic level; obtaining the total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBP to fall between the ground and the VDA, and obtaining the reverse-biased capacitance-voltage characteristics of the device.

5. A circuit for measuring capacitance and capacitance-voltage characteristics of a plurality of devices, comprising the pulse generation sub-circuit according to claim 3, and a plurality of pairs of sub-circuit Ps and sub-circuit Ns, wherein a to-be-measured device capacitor is arranged between connection nodes of each pair of sub-circuit P and sub-circuit N; all the sub-circuit Ps are connected in parallel to share a first current mirror, and all the sub-circuit Ns are connected in parallel to share a second current mirror.

6. A method for measuring capacitance and capacitance-voltage characteristics of a plurality of devices using the circuit for measuring capacitance and capacitance-voltage characteristics of a plurality of devices according to claim 5, comprising:
when measuring capacitance or capacitance-voltage characteristics of an i^{th} to-be-measured device, setting at a high level CTRPs and CTRNs in sub-circuit Ps and sub-circuit Ns in which the remaining to-be-measured devices are located, to disconnect the circuits from the first current mirror and the second current mirror, wherein only the sub-circuit P and the sub-circuit N in which the i^{th} to-be-measured device is located is connected to the first current mirror and the second current mirror and work normally; and
obtaining the capacitance and capacitance-voltage characteristics of the i^{th} to-be-measured device by using a method for measuring capacitance-voltage characteristics of a microelectronic device which comprising:
grounding a VSS, a VSA, a VBP, and a VBN, and enabling two sub-circuits to work synchronously: setting a CTRP and a CTRN at a low level, setting an LHN at a high level, and bridging a to-be-measured device capacitor Cd between connection nodes of a sub-circuit P and a sub-circuit N; turning on and off a first transmission gate and a third transmission gate synchronously, and turning off and on a second transmission gate and a fourth transmission gate synchronously, wherein potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS, the VBP, and the CTRP, setting the CTRP at a low level, setting the CTRN at a high level, connecting the VSA and the LHN to a negative power supply VSB, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, wherein in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBN to fall between the negative power supply VSB and a VDA, and obtaining the capacitance-voltage characteristics of the to-be-measured device capacitor Cd.

7. A circuit for measuring forward and reverse-biased capacitance-voltage characteristics of a plurality of devices, comprising the pulse generation sub-circuit according to claim 4, and a plurality of pairs of sub-circuit Ps and sub-circuit Ns, wherein a to-be-measured device capacitor is arranged between connection nodes of each pair of sub-circuit P and sub-circuit N; all the sub-circuit Ps are connected in parallel to share a first current mirror, and all the sub-circuit Ns are connected in parallel to share a second current mirror; VDDs connected to input terminals of first AND gates in all the sub-circuit Ps are replaced by LHPs, and VSSs connected to input terminals of first OR gates are replaced by LHPs passing through NOT gates.

8. A method for measuring forward and reverse-biased capacitance-voltage characteristics of a plurality of devices using the circuit for measuring forward and reverse-biased capacitance-voltage characteristics of a plurality of devices according to claim 7, comprising:
when measuring capacitance, capacitance-voltage characteristics, or forward and reverse-biased capacitance-voltage characteristics of an i^{th} to-be-measured device, setting at a high level CTRPs and CTRNs in sub-circuit Ps and sub-circuit Ns in which the remaining to-be-measured devices are located, to disconnect the circuits from a first current mirror and a second current mirror, wherein only a sub-circuit P and a sub-circuit N in which the i^{th} to-be-measured device is located are connected to the first current mirror and the second current mirror and work normally; and
obtaining the capacitance, the capacitance-voltage characteristics, and the forward and reverse-biased capacitance-voltage characteristics of the i^{th} to-be-measured device by using a method for measuring microelectronic device forward and reverse-biased capacitance-voltage characteristics which comprising:
replacing a VDD connected to an input terminal of a first AND gate in a sub-circuit P with an LHP, and replacing a VSS connected to an input terminal of a first OR gate with an LHP passing through a NOT gate;
grounding a VSS, a VBP, and a VBN, and enabling two sub-circuits to work synchronously: setting a CTRP and a CTRN at a low level, setting the LHP and an LHN at a high level, and bridging a to-be-measured device capacitor Cd between connection nodes of the sub-circuit P and a sub-circuit N; turning on and off a first transmission gate and a third transmission gate synchronously, turning off and on a second transmission gate and a fourth transmission gate synchronously, wherein potentials at both terminals of the to-be-measured device capacitor bridged between the two sub-circuits are equal, and the CTRP and CTRN are the beginning and end of a low-level period with zero charge variation; and obtaining parasitic capacitance C0p according to a current curve slope;
grounding the VSS and the VBP, setting the LHN and the CTRP at a low level, and setting the LHN and the CTRN at a high level, turning on the fourth transmission gate, turning off the third transmission gate, connecting one terminal of the to-be-measured device capacitor Cd to a power supply VBN through the fourth transmission gate, connecting the other terminal of the to-be-measured device capacitor Cd to the connection node of the sub-circuit P, and connecting the to-be-measured device capacitor Cd in parallel to the sub-circuit P; when a clock pulse CLK1 is at an active level and a clock pulse CLK2 is at an inactive level, turning off the second transmission gate and turning on the first transmission gate, to enable the circuit to charge the to-be-measured device capacitor Cd and an equivalent parasitic capacitor C0P through the first transmission gate; or when the clock pulse CLK2 is at an active level and the clock pulse CLK1 is at an inactive level, turning off the first transmission gate and turning on the second transmission gate, to discharge the to-be-measured device capacitor Cd through the second transmission gate; when the to-be-measured device capacitor is charged, mirroring a charging current i1 as a charging current i2 of a first large capacitor through a first current mirror in the sub-circuit P; periodically and continuously charging and discharging the to-be-measured device capacitor, to synchronously charge the first large capacitor Cw with the current i2 during a charging period, wherein in a period of time, voltage at both terminals of the first large capacitor Cw increases in an equal step on a microscopic level and increases linearly on a macroscopic level; obtaining total capacitance Cd+C0p of the to-be-measured device capacitor and the parasitic capacitor according to a current curve slope, to obtain capacitance of the to-be-measured device capacitor: Cd=(Cd+C0p)−C0p;
changing a value of the power supply VBN to fall between the negative power supply VSB and a VDA, and obtaining the capacitance-voltage characteristics of the to-be-measured device capacitor Cd;
grounding the VSS and the VBN, setting the LHP and the CTRN at a low level, setting the LHN and CTRP at a high level, turning on the second transmission gate, turning off the first transmission gate, connecting one terminal of the to-be-measured device capacitor Cd to the power supply VBN through the second transmission gate, connecting the other terminal of the to-be-measured device capacitor Cd to the connection node of the sub-circuit N, and connecting the to-be-measured device capacitor Cd in parallel to the sub-circuit N;
when the clock pulse CLK1 is at an active level and the clock pulse CLK2 is at an inactive level, turning off the fourth transmission gate and turning on the third transmission gate, to enable the circuit to charge the to-be-measured device capacitor Cd and the equivalent parasitic capacitor C0P through the third transmission gate; or when the clock pulse CLK2 is at an active level and the clock pulse CLK1 is at an inactive level, turning off the third transmission gate and turning on the fourth transmission gate, to discharge the to-be-measured device capacitor through the fourth transmission gate; when the to-be-measured device capacitor is charged, mirroring the charging current as a charging current i3 of a second large capacitor through a second current mirror in the sub-circuit N; periodically and continuously charging and discharging the to-be-measured device capacitor, to synchronously charge the second large capacitor Cw2 with the mirror current i3 during a charging period, wherein in a period of time, voltage at both terminals of the second large capacitor Cw2 increases in an equal step on a microscopic level and increases linearly on a macroscopic level; obtaining the total capacitance Cd+C0p of the to-be-measured device capacitor and the parasitic capacitor according to a current curve slope, to obtain capacitance of the to-be-measured device capacitor: Cd=(Cd+C0p)−C0p; and
changing a value of the power supply VBP to fall between the ground and the VDA, and obtaining the reverse-biased capacitance-voltage characteristics of the device.

9. A circuit for measuring capacitance and capacitance-voltage characteristics of a plurality of substrate-connected devices, comprising the pulse generation sub-circuit and the sub-circuit P according to claim 1, and further comprising a plurality of substrate sub-circuits, wherein
an i^{th} substrate-connected sub-circuit comprises a fifth transmission gate, a sixth transmission gate, a to-be-measured device capacitor Cdi and a to-be-measured device capacitor Csj; a connection node of the sub-circuit P is connected to a first terminal of the fifth transmission gate, a second terminal of the fifth transmission gate is connected to one terminal of the to-be-measured device capacitor Cdi, and the other terminal VSD of the to-be-measured device capacitor Cdi is connected to a substrate negative power supply VSB; the connection node of the sub-circuit P is further connected to a first terminal of the sixth transmission gate, a second terminal of the sixth transmission gate is connected to one terminal of the to-be-measured device capacitor Csj, and the other terminal VSC of the to-be-measured device capacitor Csj is connected to a low power supply; and
a first control terminal of the fifth transmission gate is connected to a CTRDi, and the CTRDi is connected to a second control terminal of the fifth transmission gate through a NOT gate; a first control terminal of the sixth transmission gate is connected to a CTRCj, and the CTRCj is connected to a second control terminal of the sixth transmission gate through a NOT gate.

10. A method for measuring capacitance and capacitance-voltage characteristics of a plurality of substrate-connected devices using the circuit for measuring capacitance and capacitance-voltage characteristics of a plurality of substrate-connected devices according to claim 9, comprising:
grounding a VSS, a VSA, and a VBP, and setting control signals CTRCj and CTRDi at a high level, turning off all transmission gates, and enabling a sub-circuit P to work normally;
when a clock pulse CLK1 is at an active level and a clock pulse CLK2 is at an inactive level, turning off a second transmission gate and turning on a first transmission gate, to enable the circuit to charge a total equivalent parasitic capacitor C0 through the first transmission gate; or when the clock pulse CLK2 is at an active level and the clock pulse CLK1 is at an inactive level, turning off the first transmission gate and turning on the second transmission gate, to discharge the parasitic capacitor through the second transmission gate;
when the capacitor is charged, mirroring a charging current i1 as a charging current i2 through a first current mirror; periodically and continuously charging and discharging the capacitor, to synchronously charge a first large capacitor Cw with the current i2 during a charging period, wherein in a period of time, voltage at both terminals of the first large capacitor Cw increases in an equal step on a microscopic level and increases linearly on a macroscopic level; and obtaining parasitic capacitance C0 according to a current curve slope;
setting a transmission gate control signal CTRDi of the to-be-measured device Cdi at a low level, to connect the to-be-measured device to a connection node of the sub-circuit P, and setting other control signals at a high level, to disconnect other devices;
when the clock pulse CLK1 is at an active level and the clock pulse CLK2 is at an inactive level, turning off the second transmission gate and turning on the first transmission gate, to enable the circuit to charge the to-be-measured device capacitor Cdi and the equivalent parasitic capacitor C0 through the first transmission gate; or when the clock pulse CLK2 is at an active level and the clock pulse CLK1 is at an inactive level, turning off the first transmission gate and turning on the second transmission gate, to discharge the to-be-measured device capacitor and the parasitic capacitor through the second transmission gate; when the capacitor is charged, mirroring the charging current i1 as i2 through the first current mirror; periodically and continuously charging and discharging the capacitor, to synchronously charge the first large capacitor Cw with the mirror current i2 during a charging period, wherein in a period of time, voltage at both terminals of the first large capacitor Cw increases in an equal step on a microscopic level and increases linearly on a macroscopic level; obtaining total capacitance Cdi+C0 of the to-be-measured device capacitor and the parasitic capacitor according to a current curve slope, to obtain capacitance of the to-be-measured device capacitor: Cdi=(Cdi+C0)−C0; and
changing a power supply VSD, that is, a value of a substrate negative power supply VSB, to obtain the to-be-measured device capacitance or capacitance-voltage characteristics.
